(19) United States
(12) Patent Application Publication
(10) Pub. No.: US 2011/0163768 A1
(43) Pub. Date: Jul. 7, 2011

(54) TOUCH SCREEN DEVICE, CAPACITANCE MEASURING CIRCUIT THEREOF, AND METHOD OF MEASURING CAPACITANCE

(75) Inventors: Oh Jin Kwon, Daejeon (KR); Il Hyun Yun, Daejeon (KR); Hyung Cheol Shin, Daejeon (KR); Seung Hun Ko, Seoul (KR)

(73) Assignee: SAIN InfoCom, Daejeon (KR)

(21) Appl. No.: 12/898,554

(22) Filed: Oct. 5, 2010

(30) Foreign Application Priority Data
Jan. 5, 2010 (KR) 10-2010-0000400
Jan. 5, 2010 (KR) 10-2010-0000401

(51) Int. Cl. G01R 27/26

(52) U.S. Cl. 324/686

(57) ABSTRACT

According to the present invention, a charging and discharging circuit is electrically connected to an operation signal line and a detection signal line, and repeats a charging and discharging operation of a node capacitor. The present invention also includes an integration capacitor electrically connected to the detection signal line and an integration circuit charging the integration capacitor to a unit charging voltage every charging and discharging operation of the node capacitor such that the integration capacitor is charged to a first voltage that is integrated according to a charging and discharging number. The integration circuit may include a reset switch electrically connected to the integration capacitor and discharging the first voltage integrated and charged to the integration capacitor for initializing.

### CROSS-REFERENCE TO RELATED APPLICATION

This application claims priority to and the benefit of Korean Patent Application Nos. 10-2010-0000400 and 10-2010-0000401 filed in the Korean Intellectual Property Office on Jan. 5, 2010, the entire contents of which are incorporated herein by reference.

### BACKGROUND OF THE INVENTION

(a) Field of the Invention

The present invention relates to a touch screen device, a capacitance measuring circuit of the touch screen device, and a capacitance measuring method, and particularly to a touch screen device, a capacitance measuring circuit of a touch screen device, and a capacitance measuring method, against a strong external noise.

(b) Description of the Related Art

Display devices, such as a liquid crystal display and an organic light emitting display, portable transmission devices, and other information processing devices are configured to perform their functions using a variety of input devices. Touch screen devices have recently been widely used as input devices for mobile phones, smart phones, palm-size PCs, and ATMs (automated teller machines).

In the touch screen device, a user can write letters or draw pictures by touching a finger, a touch pen, or a stylus to a screen, and can perform a desired command by executing an icon. The touch screen device can determine whether a user's finger or a touch pen has touched a screen, and a position of the screen where the user's finger or the touch pen has touched.

Such a touch screen device can be largely divided into a resistive type and a capacitive type according to the method of sensing a touch.

The resistive touch screen has a structure in which a resistive material is coated on a glass or transparent plastic plate, and a polyester film is formed on the resistive material. In the resistive touch screen, when the screen is touched, resistance is changed, and thus a contact point is sensed by detecting the change in resistance. The resistive touch screen is disadvantageous in that it does not sense a contact point when pressure is weak.

Meanwhile, in the capacitive touch screen, two electrodes are formed on both surfaces or one surface of glass or plastic and a voltage is applied between the two electrodes. When an object such as a finger contacts the screen, the change amount of the capacitance is detected between two electrodes to detect the touch point.

In the capacitive touch screen, to detect the touch point, a circuit for measuring the capacitance between the two electrodes is needed. This capacitance measuring circuit is used for measuring the capacitance of various circuits or elements. Recently, various portable devices have provided the touch input interface such that the application range of the capacitance measuring circuit that is capable of detecting the contact and the approach of the user has been extended.

However, the capacitance measuring circuit used for the touch screen such as a conventional mobile phone may be abnormally operated by various noises generated according to change of the surrounding environment.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention provides a touch screen device, a capacitance measuring circuit of a touch screen device, and a capacitance measuring method against a strong external noise.

A touch screen device of the present invention includes:

a touch panel including a plurality of operation signal lines, a plurality of detection signal lines insulated from the plurality of operation signal lines, and a plurality of node capacitors respectively formed by the corresponding operation signal lines and the corresponding detection signal lines; a capacitance measuring circuit including a switched capacitor circuit having a plurality of switches, integration capacitors, and operational amplifiers, wherein each integration capacitor is charged to a unit charging voltage during every charging and discharging operation of the node capacitor such that the integration capacitor is charged to a first voltage that is integrated according to a charging and discharging number of the node capacitor and the integration capacitor charged to the first voltage is initialized; and a touch discriminator analyzing the voltage charged to the integration capacitor measured by the capacitance measuring circuit to detect a touch point input by a user.

A capacitance measuring circuit according to the present invention is electrically connected to a plurality of operation signal lines and a plurality of detection signal lines insulated from the plurality of operation signal lines, and measures capacitance of a plurality of node capacitors respectively formed by the corresponding operation signal line and the corresponding detection signal line.

The capacitance measuring circuit includes: a charging and discharging circuit electrically connected to the operation signal line and the detection signal line and repeating a charging and discharging operation of the node capacitor several times; and an integration circuit including an operational amplifier having a first input terminal electrically connected to the detection signal line and a second input terminal electrically connected to the first voltage and an integration capacitor electrically connected between the input terminal and the output terminal of the operational amplifier, and charging the integration capacitor to a unit charging voltage every charging and discharging operation of the charging and discharging circuit such that the integration capacitor is charged to a second voltage that is integrated according to a charging and discharging number of the node capacitor and the charged integration capacitor is initialized.

A method of measuring capacitance of a capacitor electrically connected to a plurality of operation signal lines and a plurality of detection signal lines insulated from the plurality of operation signal lines, and measuring capacitance of a plurality of node capacitors respectively formed by the corresponding operation signal line and the corresponding detection signal line according to the present invention, includes:

executing a charging and discharging operation to the node capacitor; charging an integration capacitor electrically connected to the detection signal line to an unit charging voltage in response to the charging or discharging operation of the node capacitor; repeating the charging and discharging operation of the node capacitor several times; charging the integration capacitor to the unit charging voltage every charging and discharging operation of the node capacitor to charge the integration capacitor to a first voltage that is integrated according to a charging and discharging number of the node capacitor; and discharging the first voltage integrated and charged to the integration capacitor for initialization.

According to the present invention, the voltage in proportional to a multiple of the capacitance of the node capacitor and the charging and discharging number is charged to both terminals of the integration capacitor by using a switched capacitor including the integration capacitor and the operational amplifier, thereby obtaining an excellent characteristic of a low-pass filter.

### BRIEF DESCRIPTION OF THE DRAWINGS

FIG. 1 is a view of a touch screen device according to an exemplary embodiment of the present invention.

FIG. 2 is a view showing a capacitance measuring circuit according to an exemplary embodiment of the present invention.

FIG. 3 is a view showing a capacitance measuring circuit according to an exemplary embodiment of the present invention.

FIG. 4 to FIG. 7 are views showing an operation relationship of a capacitance measuring circuit according to the first exemplary embodiment of the present invention.

FIG. 8 to FIG. 11 are views showing an operation relationship of a capacitance measuring circuit according to the second exemplary embodiment of the present invention.

FIG. 12 is a view showing a capacitance measuring circuit according to another embodiment of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. In the following description, the technical terms are used only to explain a specific exemplary embodiment while not limiting the present invention. The terms of a singular form may include plural forms unless referred to the contrary.

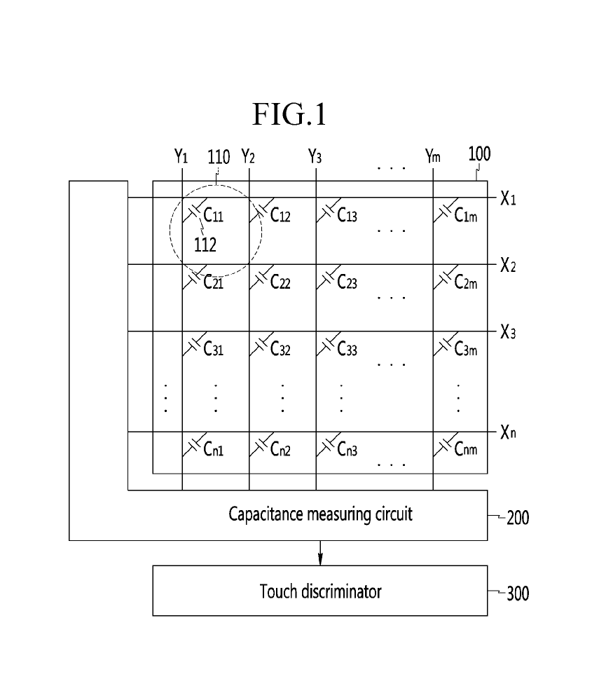

FIG. 1 is a view of a touch screen device according to an exemplary embodiment of the present invention.

As shown in FIG. 1, a touch screen device according to an exemplary embodiment of the present invention includes a touch panel 100, a capacitance measuring circuit 200, and a touch discriminator 300.

The touch panel 100 includes a plurality of operation signal lines X1, X2, X3, . . . , Xn and a plurality of detection signal lines Y1, Y2, Y3, . . . , Yn that are insulated from each other. For convenience, in FIG. 1, the operation signal lines and the detection signal lines are represented, however they are realized as an electrode pattern. In some embodiments, the detection signal line may be compatible with a first detection line, a second detection line, and a detection electrode, and the operation signal line may be compatible with a first operation line, a second operation line, and an operation electrode. Also, the plurality of operation signal lines X1, X2, X3, . . . , Xn and the plurality of detection signal lines Y1, Y2, Y3, . . . , Yn are insulated from each other

A sensing node 110 representing a touch point is defined by one detection signal line and one operation signal line, and each sensing node 110 includes a node capacitor 112. The node capacitor 112 is formed by the operation signal line and the detection signal line that are insulated and separated from each other. In FIG. 1, capacitance of the node capacitor 112 formed by the i-th operation signal line and the j-th detection signal line is denoted by Cij.

The capacitance measuring circuit 200 is electrically connected to the plurality of operation signal lines X1, X2, X3, . . . , Xn and the plurality of detection signal lines Y1, Y2, Y3, . . . , Yn, thereby measuring the capacitance Cij of each node capacitor 112.

The touch discriminator 300 analyses the change in capacitance based on the capacitance of each node capacitor measured by the capacitance measuring circuit 200 to detect the touch point input by the user.

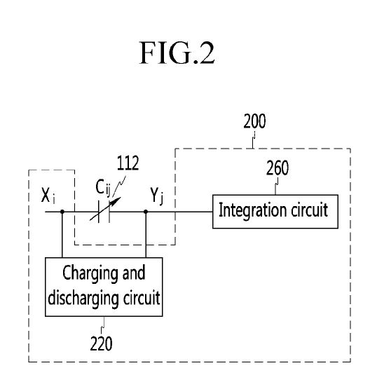

FIG. 2 is a block diagram of a capacitance measuring circuit according to an exemplary embodiment of the present invention.

As shown in FIG. 2, the capacitance measuring circuit includes a charging and discharging circuit 220 and an integration circuit 260.

The charging and discharging circuit 220 is electrically connected to the operation signal line Xi as one terminal of the node capacitor 112 and the detection signal line Yj as the other terminal of the node capacitor 112, and is a circuit for charging the node capacitor 112 to the power voltage VDD and discharging it to the ground voltage GND. Here, the charging and discharging circuit 200 according to an exemplary embodiment of the present invention repeats the charging and discharging operation a plurality of times (N times). Hereafter, the number of times that the charging and discharging operation is repeated is referred to as “charging and discharging number”.

The integration circuit 260 includes an integration capacitor (not shown) electrically connected to the detection signal line Yj as the other terminal of the node capacitor 112. According to an exemplary embodiment of the present invention, both terminals of the integration capacitor are charged with the voltage in proportion to a multiple of the capacitance Cij and the charging and discharging number. That is, both terminals of a reference capacitor are charged with a unit charging voltage every charging and discharging operation, and if the charging and discharging number is N, a voltage of which the unit charging voltage is integrated N times is charged. Here, the unit charging voltage is proportional to the capacitance Cij of the node capacitor that will be described later.

The touch discriminator 300 analyses the voltage charged to both terminals of the integration capacitor of the integration circuit 260 to detect the touch point input by the user. In detail, according to an exemplary embodiment of the present invention, when the object such as the finger contacts or approaches the touch screen, the capacitance Cij of the node capacitor 112 is changed such that the voltage charged to both terminals of the integration capacitor of the integration circuit 260 is changed, and accordingly the touch discriminator 300 detects the sensing node at which both terminals of the integration capacitor are changed and the touch point input by the user may be confirmed.

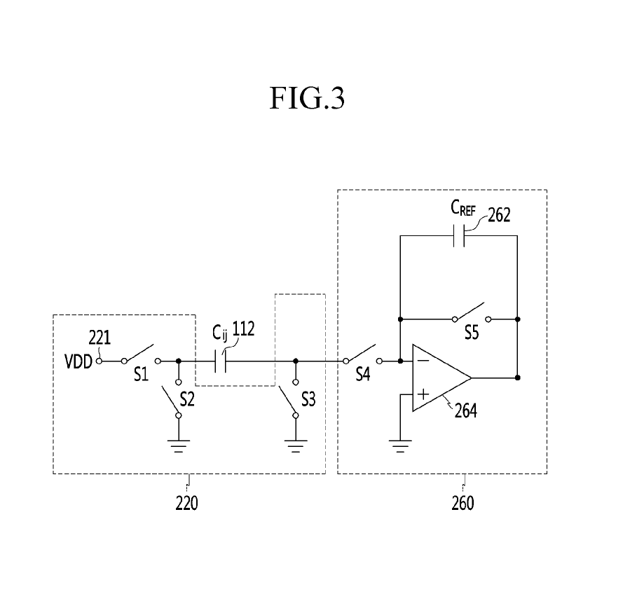

FIG. 3 is a detailed circuit diagram of a capacitance measuring circuit according to an exemplary embodiment of the present invention.

As shown in FIG. 3, the charging and discharging unit 220 includes a power input unit 221 applied with the power voltage VDD, a power input switch S1, a first ground switch S2, and a second ground switch S3.

The power input switch S1 is electrically connected between the power input unit 221 and one terminal (i.e., operation signal line) of the node capacitor 112, and the first ground switch S2 is electrically connected between one terminal (i.e., operation signal line) of the node capacitor 112 and the ground. The second ground switch S3 is electrically connected between the other terminal (i.e., detection signal line) of the capacitor 112 and the ground.

The integration circuit 260 includes an integration capacitor 262, an amplifier 264, an output shorting switch S4, and a reset switch S5.

The amplifier 264 is a differential amplifier, and the inversion terminal is connected to the other terminal of the node capacitor 112 and the non-inversion terminal is grounded. Hereafter, a general operational amplifier (OP AMP) will be described as an example of the amplifier 264, however the present invention is not limited thereto, and another differential amplifier may be used.

The integration capacitor 262 is electrically connected between the inversion terminal of the operational amplifier 264 and the output terminal of the operational amplifier 264. That is, the integration capacitor 262 has a function to negatively feed back the output of the operational amplifier 264 to the input of the operational amplifier 264. According to an exemplary embodiment of the present invention, as described later, both terminals of the integration capacitor 262 are charged with the voltage in proportion to the multiple of the capacitance Cij and the charging and discharging number of the node capacitor 112 in response to the charging and discharging operation of the charging and discharging circuit 200.

The output shorting switch S4 is connected between the other terminal 112 of the node capacitor and the inversion terminal of the integration capacitor 262, and has the function of switching to transmit the voltage charged to the node capacitor 112 to the integration capacitor.

The reset switch S5 is connected to both terminals of the integration capacitor 112, and has the function of discharging the voltage charged to the integration capacitor 262 for initialization.

As described above, the capacitance measuring circuit according to an exemplary embodiment of the present invention includes the switch that is periodically turned on/off, the integration capacitor, and the operational amplifier, thereby executing the function of the switched capacitor filter.

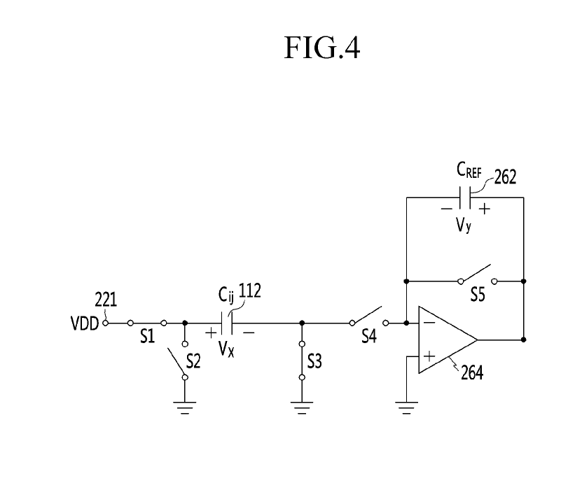

Next, an operation relationship of a capacitance measuring circuit according to the first exemplary embodiment of the present invention will be described with reference to FIG. 4 to FIG. 7.

According to an exemplary embodiment of the present invention, the charging and discharging operation is repeated a predetermined number of times.

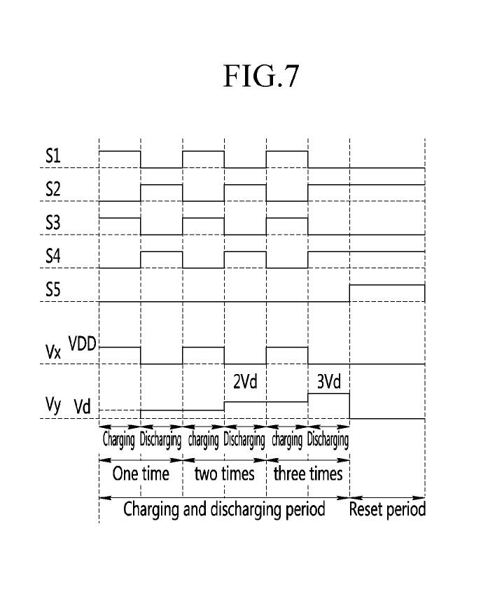

To describe the charging operation of the node capacitor 112, as shown in FIG. 4, the power input switch S1 and the output ground switch S3 are turned on, and the input ground switch S2 and the output shorting switch S4 are turned off. In this case, as shown in FIG. 7, a voltage Vx of both terminals of the node capacitor 112 is charged by the voltage VDD.

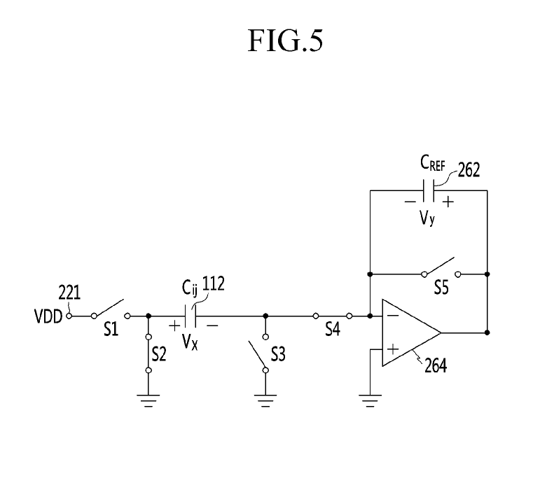

Next, the discharging operation of the node capacitor 112 is executed, as shown in FIG. 5, and the power input switch S1 and the output ground switch S3 are turned off and the input ground switch S2 and the output shorting switch S4 are turned on. In this case, the voltage Vx of both terminals of the node capacitor 112 of FIG. 7 is discharged to the ground potential, and the voltage Vy of both terminals of the integration capacitor 262 is charged by the unit charging voltage Vd.

Here, the unit charging voltage Vd is determined by Equation 1.

$$Vd = \frac{Cij}{Cref} VDD \qquad [ Equation 1 ]$$

Here, Vd is the unit charging voltage, Cij is the capacitance of the node capacitor, Cref is the capacitance of the integration capacitor, and VDD is the power voltage.

According to the first exemplary embodiment of the present invention, as shown in Equation 1, under the discharging operation of the node capacitor 112, the integration capacitor is charged with the unit charging voltage Vd in proportion to the capacitance of the node capacitor.

Next, the second charging and discharging operation is started.

The switch operation of the second charging operation is the same as in FIG. 4, and in this case, as shown in FIG. 7, voltage Vx of both terminals of the node capacitor 112 is charged with the voltage VDD, and the voltage Vy of both terminals of the integration capacitor 262 is maintained as the unit charging voltage Vd.

Next, the second discharging operation is started, and the switch operation of the second discharging operation is the same as in FIG. 5. In this case, as shown in FIG. 7, the voltage Vx of both terminals of the node capacitor 112 is discharged to the ground potential and the integration capacitor 262 is additionally charged by the unit charging voltage Vd, and as a result, the voltage Vy of both terminals of the integration capacitor 262 is charged to 2 Vd.

As described above, the charging and discharging operation of the charging and discharging circuit 220 is repeated N times, and in this case, the voltage Vy of both terminals of the integration capacitor 262 is charged to the voltage corresponding to N*Vd. That is, both terminals of the integration capacitor 262 are additionally charged and integrated by the unit charging voltage Vd every charging and discharging operation, thereby being charged to the voltage corresponding to N*Vd.

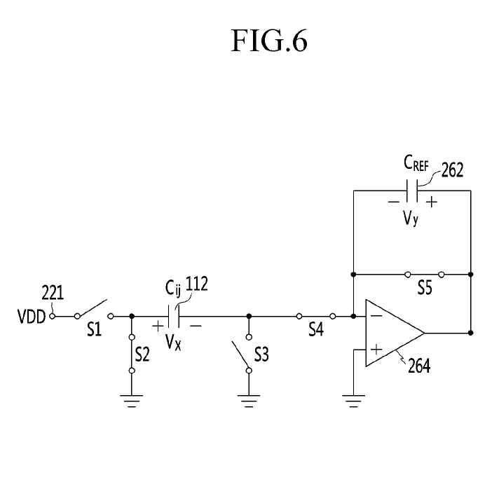

According to the first exemplary embodiment of the present invention, if the repeating number of the charging and discharging operation is over the predetermined number (three in FIG. 7), the voltage charged to the integration capacitor 262 is discharged and initialized. That is, as shown in FIG. 6, the reset switch S5 and the output shorting switch S4 are turned on to discharge the voltage 3*VDD charged to the integration capacitor 262 such that the voltage of both terminals of the integration capacitor becomes 0.

In an exemplary embodiment of the present invention shown in FIG. 7, when the charging and discharging number (i.e., the additional charging number of the integration capacitor) of the charging and discharging circuit is over the predetermined number, the reset switch S5 and the output shorting switch S4 are turned on to discharge the integration capacitor 262 for the initialization, however the present invention is not limited thereto. For example, regardless of the charging and discharging number, when the voltage charged to the integration capacitor 262 is more than the predetermined voltage, it is possible to discharge the integration capacitor 262 for the initialization.

Also, in an exemplary embodiment of the present invention, the discharging of the integration capacitor 262 is realized by turning on the reset switch S5 and the output shorting switch S4, however the integration capacitor 262 may be discharged through another method, as would be apparent to those of skill in the art based on the foregoing disclosure.

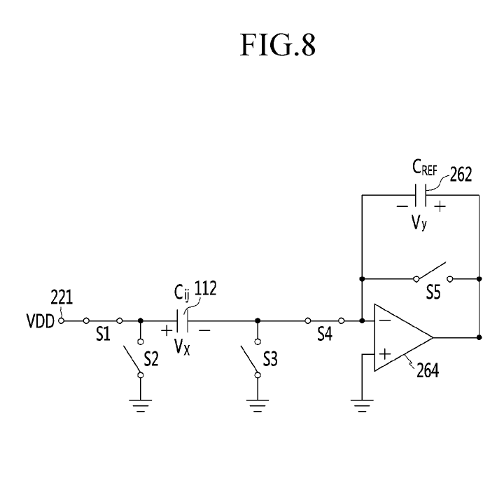

Next, an operational relationship of a capacitance measuring circuit according to a second exemplary embodiment of the present invention will be described with reference to FIG. 8 to FIG. 11.

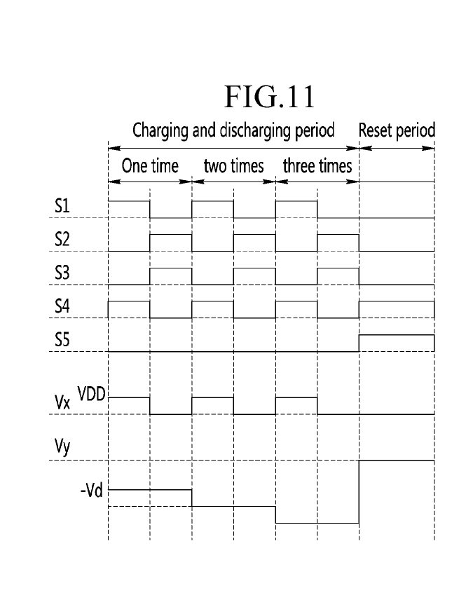

For the description of the charging operation of the node capacitor 112, as shown in FIG. 8, the power input switch S1 and the output shorting switch S4 are turned on, and the input ground switch S2 and the output ground switch S3 are turned off. In this case, as shown in FIG. 11, the voltage Vx of both terminals of the node capacitor 112 is charged by the voltage VDD, and the voltage Vy of both terminals of the integration capacitor 262 is charged to the negative unit charging voltage −Vd. Here, the voltage Vd is determined by the above-described equation. Unlike the first exemplary embodiment, according to the second exemplary embodiment of the present invention, under the charging operation of the node capacitor 112, the integration capacitor is charged to the unit charging voltage Vd in proportion to the capacitance of the node capacitor.

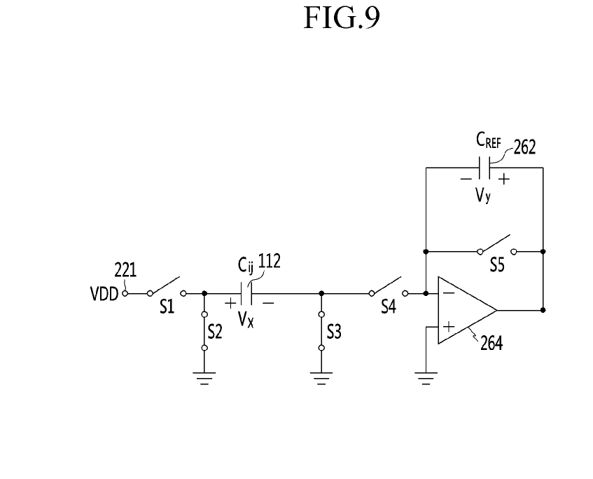

Next, the discharging operation of the node capacitor 112 is executed, and as shown in FIG. 9, the power input switch S1 and the output shorting switch S4 are turned off, and the input ground switch S2 and the output ground S3 are turned on. In this, as shown in FIG. 11, the voltage Vx of both terminals of the node capacitor 112 is discharged to the ground potential, and the voltage Vy of both terminals of the integration capacitor 262 is maintained as −Vd.

Next, the second charging and discharging operation is started.

The switch operation of the second charging operation is the same as in FIG. 8, and in this case, as shown in FIG. 11, the voltage Vx of both terminals of the node capacitor 112 is charged by the voltage VDD, and the voltage Vy of both terminals of the integration capacitor 262 is additionally charged by −Vd such that the voltage Vy of both terminals of the integration capacitor 262 is charged to −2 Vd.

Next, the second discharging operation is started, and the switch operation of the second discharging operation is the same as in FIG. 9, and in this case, as shown in FIG. 11, the voltage Vx of both terminals of the node capacitor 112 is discharged to the ground potential, and the voltage Vy of both terminals of the integration capacitor 262 is maintained as −2 Vd.

This charging and discharging operation of the charging and discharging circuit 220 is repeated N times, and in this case, the voltage Vy of both terminals of the integration capacitor 262 is charged to the voltage corresponding to N*(−Vd).

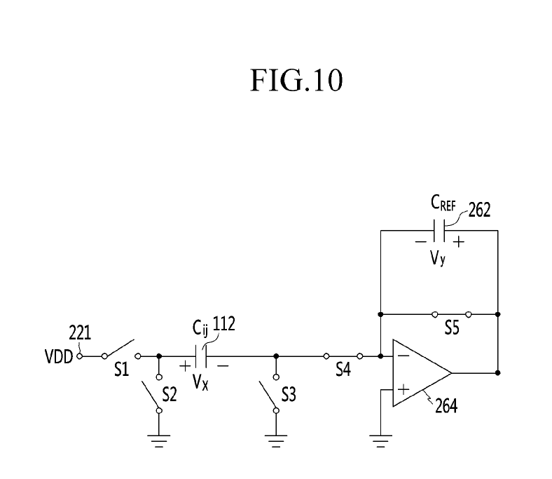

According to the second embodiment of the present invention, when the repeated times of the charging and discharging operation exceeds the predetermined number (three in FIG. 7) or the voltage charged to the integration capacitor 262 is more than the predetermined voltage, as shown in FIG. 10, the reset switch S5 and the output shorting switch S4 are turned on such that the voltage 3*(−Vd) charged to the integration capacitor 262 is discharged, and thereby the voltage of both terminals of the integration capacitor becomes 0.

In an exemplary embodiment of the present invention shown in FIG. 11, if the charging and discharging number of the charging and discharging circuit is more than the predetermined number, the reset switch S5 and the output shorting switch S4 are turned on for discharging the integration capacitor 262, however when the voltage charged to the integration capacitor 262 is more than the predetermined voltage regardless of the charging and discharging number, it is possible to discharge the integration capacitor 262 for the initialization.

As described above, according to an exemplary embodiment of the present invention, the node capacitor 112 repeatedly executes the charging and discharging.

Accordingly, the capacitance measuring circuit according to an exemplary embodiment of the present invention uses the switched capacitor including the switch, the integration capacitor, and the operational amplifier, thereby basically having the characteristic of a FIR (finite impulse response) filter.

In detail, in the case that the capacitance measuring circuit according to an exemplary embodiment of the present invention executes the charging and discharging N times, it is operated as a FIR filter having N tabs. That is, the driving circuit according to an exemplary embodiment of the present invention is operated as a low-pass filter having a different frequency response according to the charging and discharging number N, and as N is increased, the characteristic of the low-pass filter has an excellent effect.

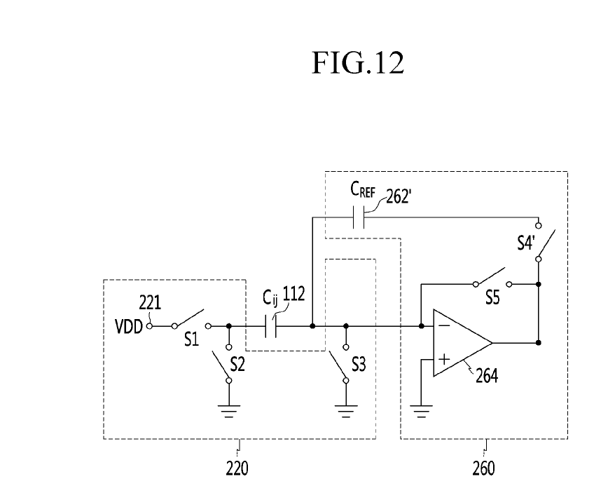

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. For example, the charging and discharging circuit shown in FIG. 3 according to an exemplary embodiment of the present invention may be realized by the circuit shown in FIG. 12, and the operation of the circuit shown in FIG. 12 is understood through the above description by a person of ordinary skill in the art such that a detailed description is omitted.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

100: touch screen panel 200: capacitance measuring circuit 300: touch discriminator 220: charging and discharging circuit 112: node capacitor 262: integration capacitor 264: operational amplifier S1: power input switch S2: input ground switch S3: output ground switch S4: output shorting switch S5: reset switch

What is claimed is:

1. A touch screen device comprising:
a touch panel including a plurality of operation signal lines, a plurality of detection signal lines insulated from the plurality of operation signal lines, and a plurality of node capacitors respectively formed by the corresponding operation signal lines and the corresponding detection signal lines;
a capacitance measuring circuit including a switched capacitor circuit having a plurality of switches, integration capacitors, and operational amplifiers, wherein the integration capacitor is charged to a unit charging voltage during every charging and discharging operation of the node capacitor such that the integration capacitor is charged to a first voltage that is integrated according to a charging and discharging number of the node capacitor and the integration capacitor charged into the first voltage is initialized; and
a touch discriminator configured to analyze the voltage charged to the integration capacitor measured by the capacitance measuring circuit to detect a touch point input by a user.

2. The touch screen device of claim 1, wherein
the capacitance measuring circuit includes:
a charging and discharging circuit electrically connected to the operation signal line and the detection signal line, the charging and discharging circuit being configured to repeat a charging and discharging operation of the node capacitor several times; and
an integration circuit including an operational amplifier having a first input terminal electrically connected to the other terminal of the node capacitor and a second input terminal electrically connected to the second voltage, an integration capacitor electrically connected to the input terminal and the output terminal of the operational amplifier, and a reset switch electrically connected to the integration capacitor, wherein the integration capacitor is configured to discharge the first voltage, the first voltage being integrated and charged to the integration capacitor for the initialization.

3. The touch screen device of claim 2, wherein
the reset switch is configured to operate when the charging and discharging number of the node capacitor is over a predetermined reference number such that the first voltage integrated and charged to the integration capacitor is discharged to be initialized.

4. The touch screen device of claim 2, wherein
the reset switch is configured to operate when the first voltage integrated and charged to the integration capacitor is more than a reference voltage such that the first voltage charged to the integration capacitor is discharged to be initialized.

5. A capacitance measuring circuit electrically connected to a plurality of operation signal lines and a plurality of detection signal lines insulated from the plurality of operation signal lines, and measuring capacitance of a plurality of node capacitors respectively formed by the corresponding operation signal line and the corresponding detection signal line, comprising:
a charging and discharging circuit electrically connected to the operation signal line and the detection signal line and repeating a charging and discharging operation of the node capacitor several times; and
an integration circuit including an operational amplifier having a first input terminal electrically connected to the detection signal line and a second input terminal electrically connected to the first voltage and an integration capacitor electrically connected between the input terminal and the output terminal of the operational amplifier, and charging the integration capacitor to a unit charging voltage every charging and discharging operation of the charging and discharging circuit such that the integration capacitor is charged to a second voltage that is integrated according to a charging and discharging number of the node capacitor, and the charged integration capacitor is initialized.

6. The capacitance measuring circuit of claim 5, wherein
the charging and discharging circuit includes:
a first switch electrically connected between the operation signal line and the third voltage;
a second switch electrically connected between the operation signal line and the fourth voltage; and
a third switch electrically connected between the detection signal line and the fourth voltage.

7. The capacitance measuring circuit of claim 6, wherein
the integration circuit includes
a fourth switch electrically connected between the detection signal line and the first input terminal of the integration capacitor and switching to transmit the voltage charged to the node capacitor to the integration capacitor, and
a reset switch electrically connected to the integration capacitor and discharging the second voltage integrated and charged to the integration capacitor for initialization.

8. The capacitance measuring circuit of claim 7, wherein
the reset switch is operated when the charging and discharging number of the node capacitor is over a predetermined reference number such that the second voltage integrated and charged to the integration capacitor is discharged to be initialized.

9. The capacitance measuring circuit of claim 7, wherein
the reset switch is operated when the second voltage integrated and charged to the integration capacitor is more than a reference voltage such that the second voltage charged to the integration capacitor is discharged to be initialized.

10. The capacitance measuring circuit of claim 5, wherein
the first voltage and the fourth voltage are a ground voltage.

11. The capacitance measuring circuit of claim 5, wherein
the integration circuit additionally charges the unit charging voltage corresponding to the voltage charged to the node capacitor to the integration capacitor before the discharging operation of the node capacitor, and maintains the voltage integrated and charged to the integration capacitor under the charging operation of the node capacitor.

12. The capacitance measuring circuit of claim 5, wherein
the integration circuit charges the unit charging voltage corresponding to the voltage charged to the node capacitor under the charging operation of the node capacitor to the integration capacitor, and maintains the voltage integrated and charged to the integration capacitor under the discharging operation of the node capacitor.

13. A method for measuring capacitance of a capacitor electrically connected to a plurality of operation signal lines and a plurality of detection signal lines insulated from the plurality of operation signal lines, and measuring capacitance of a plurality of node capacitors respectively formed by the corresponding operation signal line and the corresponding detection signal line, comprising:
executing a charging and discharging operation to the node capacitor;
charging an integration capacitor electrically connected to the detection signal line to a unit charging voltage in response to the charging or discharging operation of the node capacitor;
repeating the charging and discharging operation of the node capacitor several times;
charging the integration capacitor to the unit charging voltage every charging and discharging operation of the node capacitor to charge the integration capacitor to a first voltage that is integrated according to a charging and discharging number of the node capacitor; and
discharging the first voltage integrated and charged to the integration capacitor for initialization.

14. The method of claim 13, wherein
the first voltage corresponds to the charging and discharging number of the node capacitor and the detection capacitance.

15. The method of claim 13, wherein the first voltage integrated and charged to the integration capacitor is discharged and is initialized when the charging and discharging number of the node capacitor is more than a reference number.

16. The method of claim 13, wherein the first voltage integrated and charged to the integration capacitor is discharged and is initialized when the first voltage integrated and charged to the integration capacitor is more than a reference voltage.

17. The method of claim 14, wherein the first voltage integrated and charged to the integration capacitor is discharged and is initialized when the charging and discharging number of the node capacitor is more than a reference number.

18. The method of claim 14, wherein the first voltage integrated and charged to the integration capacitor is discharged and is initialized when the first voltage integrated and charged to the integration capacitor is more than a reference voltage
